(19) United States
(12) Patent Application Publication
(10) Pub. No.: US 2025/0324610 A1
(43) Pub. Date: Oct. 16, 2025

(54) FERROELECTRIC MEMORY DEVICE WITH LEAKAGE BARRIER LAYERS

(71) Applicant: Taiwan Semiconductor Manufacturing Company, Ltd., Hsinchu (TW)

(72) Inventors: Fu-Chen Chang, New Taipei City (TW); Tzu-Yu Chen, Kaohsiung City (TW); Sheng-Hung Shih, Hsinchu City (TW); Kuo-Chi Tu, Hsin-Chu (TW); Wen-Ting Chu, Kaohsiung City (TW)

(21) Appl. No.: 19/251,924

(22) Filed: Jun. 27, 2025

Related U.S. Application Data
(62) Division of application No. 17/672,355, filed on Feb. 15, 2022.

(51) Int. Cl. H10B 53/30

(52) U.S. Cl. CPC H10B 53/30

(57) ABSTRACT

The present disclosure relates to an integrated chip including a first ferroelectric layer over a substrate. A first electrode layer is over the substrate and on a first side of the first ferroelectric layer. A second electrode layer is over the substrate and on a second side of the first ferroelectric layer, opposite the first side. A first barrier layer is between the first ferroelectric layer and the first electrode layer. A bandgap energy of the first barrier layer is greater than a bandgap energy of the first ferroelectric layer.

### REFERENCE TO RELATED APPLICATION

This Application is a Divisional of U.S. application Ser. No. 17/672,355, filed on Feb. 15, 2022, the contents of which are hereby incorporated by reference in their entirety.

### BACKGROUND

Many modern day electronic devices contain electronic memory. Electronic memory may be volatile memory or non-volatile memory. Non-volatile memory is able to store data in the absence of power, whereas volatile memory is not. Some examples of next generation electronic memory include ferroelectric random-access memory (FeRAM), magnetoresistive random-access memory (MRAM), resistive random-access memory (RRAM), phase-change random-access memory (PCRAM), and conductive-bridging random-access memory (CBRAM).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a ferroelectric capacitor comprising a first electrode layer, a second electrode layer, a first ferroelectric layer between the first electrode layer and the second electrode layer, and a first barrier layer between the first electrode layer and the first ferroelectric layer.

FIG. 2 illustrates an energy band diagram corresponding to some embodiments of the ferroelectric capacitor of FIG. 1.

FIG. 3 illustrates a cross-sectional view of some embodiments of a ferroelectric capacitor comprising a first electrode layer, a second electrode layer, a first ferroelectric layer between the first electrode layer and the second electrode layer, and a first barrier layer between the second electrode layer and the first ferroelectric layer.

FIG. 4 illustrates a cross-sectional view of some embodiments of the ferroelectric capacitor of FIG. 1, further comprising a second barrier layer between the first ferroelectric layer and the second electrode layer.

FIG. 5 illustrates a cross-sectional view of some embodiments of the ferroelectric capacitor of FIG. 3, further comprising a second ferroelectric layer between the first barrier layer and the second electrode layer.

FIG. 6 illustrates a cross-sectional view of some embodiments of the ferroelectric capacitor of FIG. 4, further comprising a second ferroelectric layer between the second barrier layer and the second electrode layer.

FIG. 7 illustrates a cross-sectional view of some embodiments of the ferroelectric capacitor of FIG. 5, further comprising a second barrier layer between the second ferroelectric layer and the second electrode layer.

FIG. 8 illustrates a cross-sectional view of some embodiments of the ferroelectric capacitor of FIG. 6, further comprising a third barrier layer between the second ferroelectric layer and the second electrode layer.

FIG. 9 illustrates a cross-sectional view of some embodiments of an integrated chip including the ferroelectric capacitor of FIG. 8 over a transistor device.

FIGS. 10-13 illustrate cross-sectional views of some embodiments of an integrated chip including the ferroelectric capacitor of FIG. 8 over a transistor device.

FIGS. 14-20 illustrate cross-sectional views of some embodiments of a method for forming an integrated chip including a ferroelectric capacitor over a transistor device, the ferroelectric capacitor including a first barrier layer.

FIGS. 21-28 illustrate cross-sectional views of some other embodiments of a method for forming an integrated chip including a ferroelectric capacitor over a transistor device, the ferroelectric capacitor including a first barrier layer.

FIG. 29 illustrates a flow diagram of some embodiments of a method for forming an integrated chip including a ferroelectric capacitor over a transistor device, the ferroelectric capacitor including a first barrier layer.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some integrated chips include memory devices. For example, some integrated chips include ferroelectric random-access memory (FeRAM) devices that include a plurality of FeRAM memory cells. Some FeRAM memory cells include a ferroelectric capacitor coupled to a transistor device. For example, a transistor device is disposed along a substrate and a ferroelectric capacitor is arranged over the transistor device. The ferroelectric capacitor includes a ferroelectric layer between a lower electrode and an upper electrode. The ferroelectric capacitor may be coupled to a source/drain of the transistor device or a gate of the transistor device.

An FeRAM memory cell can be read and/or written by applying an electric field to the ferroelectric layer (i.e., by applying a voltage across the ferroelectric layer). When the electric field is applied to the ferroelectric layer, the ferroelectric layer is polarized in a first direction (e.g., corresponding to a logic “0”) or a second direction (e.g., corresponding to a logic “1”), opposite the first direction, depending on the direction of the applied electric field (i.e., depending on the sign of the voltage applied across the ferroelectric layer).

A challenge with some FeRAM cells is that a leakage current path may be formed within the ferroelectric layer after a number of read and write cycles are performed. For example, electrons passing through the ferroelectric layer during the read and write cycles may damage the ferroelectric layer. A leakage current path may be formed within the ferroelectric layer along the damaged areas. The leakage current may reduce a data retention of the FeRAM cell. As a result, the FeRAM cell may experience increased data loss. In short, a performance of the FeRAM cell may be reduced due to the leakage current.

Various embodiments of the present disclosure are related to a ferroelectric memory device including a ferroelectric layer and a barrier layer, neighboring the ferroelectric layer, for improving a performance of the memory device. The ferroelectric layer is arranged over a substrate. A first electrode layer is over the substrate and on a first side of the ferroelectric layer. A second electrode layer is over the substrate and on a second side of the ferroelectric layer, opposite the first side. The barrier layer is between the ferroelectric layer and the first electrode layer.

A bandgap energy (e.g., a difference between a conduction band edge energy and a valence band edge energy) of the barrier layer is greater than a bandgap energy of the ferroelectric layer. Consequently, the barrier layer forms an electron/hole barrier between the first electrode layer and the ferroelectric layer which may impede leakage current from passing through the ferroelectric layer. Thus, a data retention of the ferroelectric layer may be improved and a data loss of the ferroelectric memory device may be reduced. In short, by including the barrier layer in the ferroelectric memory device between the ferroelectric layer and the first electrode layer, a performance of the ferroelectric memory device may be improved.

FIG. 1 illustrates a cross-sectional view 100 of some embodiments of a ferroelectric capacitor 101 comprising a first electrode layer 104, a second electrode layer 110, a first ferroelectric layer 108 between the first electrode layer 104 and the second electrode layer 110, and a first barrier layer 106 between the first electrode layer 104 and the first ferroelectric layer 108.

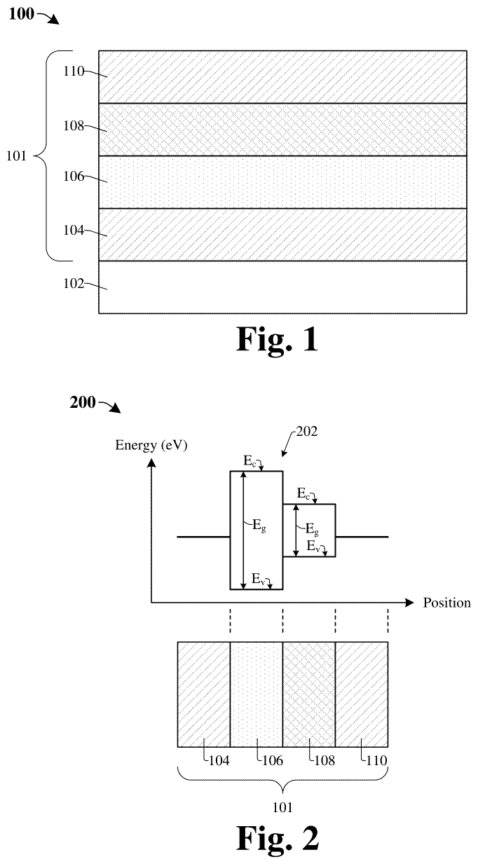

FIG. 2 illustrates an energy band diagram 200 corresponding to some embodiments of the ferroelectric capacitor 101 of FIG. 1.

Referring to FIG. 1, the ferroelectric capacitor 101 is over a substrate 102. The first electrode layer 104 is over the substrate 102. The first barrier layer is on the first electrode layer 104. The first ferroelectric layer 108 is on the first barrier layer 106. The second electrode layer 110 is on the first ferroelectric layer 108. In other words, the first electrode layer 104 is on a first side of the first ferroelectric layer 108, the second electrode layer 110 is on a second side of the first ferroelectric layer 108, opposite the first side, and the first barrier layer 106 is between the first ferroelectric layer 108 and the first electrode layer 104. In some embodiments, the first barrier layer 106 is in direct contact with a lower surface of the first ferroelectric layer 108.

Referring to FIGS. 1 and 2 simultaneously, a bandgap energy E_{g} of the first barrier layer 106 is greater than a bandgap energy E_{g} of the first ferroelectric layer 108, as illustrated in FIG. 2. In some embodiments, a conduction band edge energy E_{c} of the first barrier layer 106 is greater than a conduction band edge energy E_{c} of the first ferroelectric layer 108, and a valence band edge energy Eᵥ of the first barrier layer 106 is less than a valence band edge energy Eᵥ of the first ferroelectric layer 108. Thus, the first barrier layer 106 forms an electron/hole barrier 202 between the first ferroelectric layer 108 and the first electrode layer 104. The electron/hole barrier 202 may impede leakage current from passing through the first ferroelectric layer 108. By reducing a leakage of the first ferroelectric layer 108, a performance (e.g., a data retention or the like) of the ferroelectric capacitor 101 may be improved.

The first electrode layer 104 comprises a first conductive material. The second electrode layer 110 comprises a second conductive material. The first ferroelectric layer 018 comprises a first ferroelectric material. The first barrier layer 106 comprises a first barrier material, different from the first conductive material, the second conductive material, and the first ferroelectric material. In some embodiments, the first barrier material is or comprises an insulator (e.g., an electrically insulative material), an amorphous solid, an amorphous insulator, or some other suitable material.

Although electrode layer 104 is referred to as the first electrode layer and electrode layer 110 is referred to as the second electrode layer, it will be appreciated that the numbering may be changed. For example, electrode layer 104 could alternatively be referred to as the second electrode layer and electrode layer 110 could alternatively be referred to as the first electrode layer.

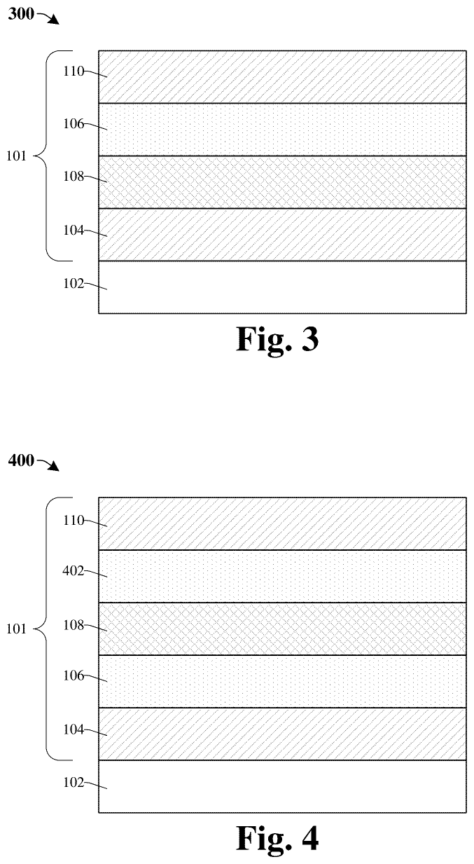

FIG. 3 illustrates a cross-sectional view 300 of some embodiments of a ferroelectric capacitor 101 comprising a first electrode layer 104, a second electrode layer 110, a first ferroelectric layer 108 between the first electrode layer 104 and the second electrode layer 110, and a first barrier layer 106 between the second electrode layer 110 and the first ferroelectric layer 108.

The first ferroelectric layer 108 is on the first electrode layer 104. The first barrier layer 106 is on the first ferroelectric layer 108. The second electrode layer 110 is on the first barrier layer 106. In some embodiments, the first barrier layer 106 is in direct contact with an upper surface of the first ferroelectric layer 108. The first barrier layer 106 forms an electron/hole barrier between the first ferroelectric layer 108 and the second electrode layer 110.

FIG. 4 illustrates a cross-sectional view 400 of some embodiments of the ferroelectric capacitor 101 of FIG. 1, further comprising a second barrier layer 402 between the first ferroelectric layer 108 and the second electrode layer 110.

The second barrier layer 402 is on the first ferroelectric layer 108. The second electrode layer 110 is on the second barrier layer 402. In some embodiments, the first barrier layer 106 is in direct contact with a lower surface of the first ferroelectric layer 108, and the second barrier layer 402 is in direct contact with an upper surface of the first ferroelectric layer 108.

A bandgap energy of the first barrier layer 106 is greater than a bandgap energy of the first ferroelectric layer 108. Thus, the first barrier layer 106 forms a first electron/hole barrier between the first ferroelectric layer 108 and the first electrode layer 104. Further, a bandgap energy of the second barrier layer 402 is greater than a bandgap energy of the first ferroelectric layer 108. Thus, the second barrier layer 402 forms a second electron/hole barrier between the first ferroelectric layer 108 and the second electrode layer 110. By including the second barrier layer 402 and thus the second electron/hole barrier in the ferroelectric capacitor 101, a leakage of the ferroelectric capacitor 101 may be further reduced.

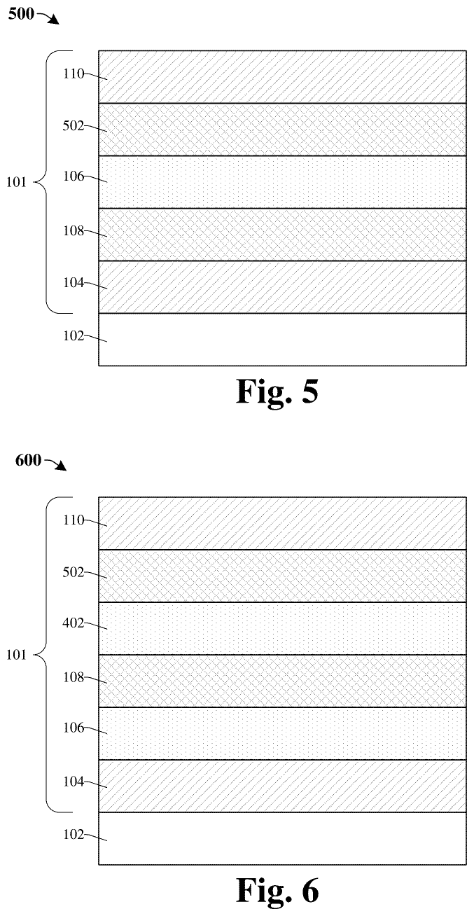

FIG. 5 illustrates a cross-sectional view 500 of some embodiments of the ferroelectric capacitor 101 of FIG. 3, further comprising a second ferroelectric layer 502 between the first barrier layer 106 and the second electrode layer 110.

The second ferroelectric layer 502 is on the first barrier layer 106. The second electrode layer 110 is on the second ferroelectric layer 502. In some embodiments, the first barrier layer 106 is in direct contact with an upper surface of the first ferroelectric layer 108 and a lower surface of the second ferroelectric layer 502.

A bandgap energy of the first barrier layer 106 is greater than both a bandgap energy of the first ferroelectric layer 108 and a bandgap energy of the second ferroelectric layer 502. Thus, the first barrier layer 106 forms an electron/hole barrier between the first ferroelectric layer 108 and the second ferroelectric layer 502.

FIG. 6 illustrates a cross-sectional view 600 of some embodiments of the ferroelectric capacitor 101 of FIG. 4, further comprising a second ferroelectric layer 502 between the second barrier layer 402 and the second electrode layer 110.

The second ferroelectric layer 502 is on the second barrier layer 402. The second electrode layer 110 is on the second ferroelectric layer 502. In some embodiments, the first barrier layer 106 is in direct contact with a lower surface of the first ferroelectric layer 108, the second barrier layer 402 is in direct contact with an upper surface of the first ferroelectric layer 108, and the second barrier layer 402 is in direct contact with a lower surface of the second ferroelectric layer 502.

A bandgap energy of the first barrier layer 106 is greater than a bandgap energy of the first ferroelectric layer 108. Thus, the first barrier layer 106 forms a first electron/hole barrier between the first ferroelectric layer 108 and the first electrode layer 104. In some embodiments, the bandgap energy of first barrier layer 106 may also be greater than that of the second ferroelectric layer 502. In some other embodiments, the bandgap energy of first barrier layer 106 may alternatively be less than that of the second ferroelectric layer 502.

Further, a bandgap energy of the second barrier layer 402 is greater than both a bandgap energy of the first ferroelectric layer 108 and a bandgap energy of the second ferroelectric layer 502. Thus, the second barrier layer 402 forms a second electron/hole barrier between the first ferroelectric layer 108 and the second ferroelectric layer 502.

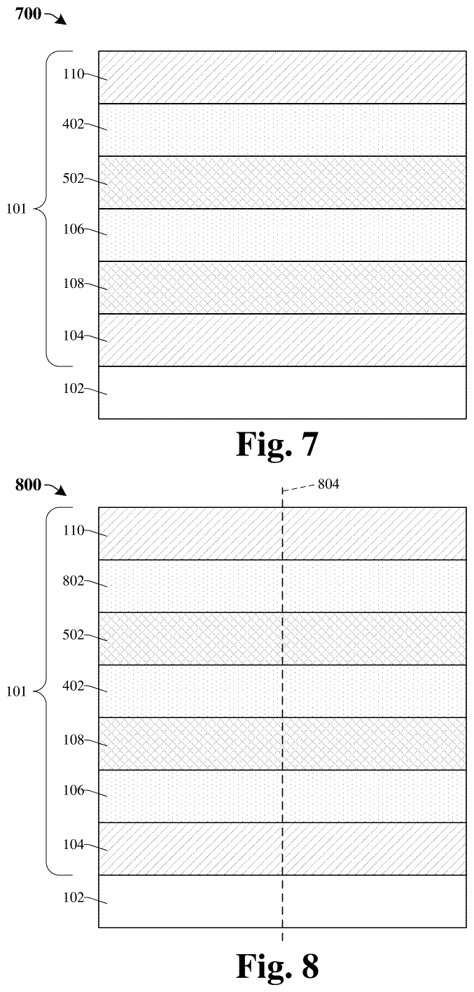

FIG. 7 illustrates a cross-sectional view 700 of some embodiments of the ferroelectric capacitor 101 of FIG. 5, further comprising a second barrier layer 402 between the second ferroelectric layer 502 and the second electrode layer 110.

The second barrier layer 402 is on the second ferroelectric layer 502. The second electrode layer 110 is on the second barrier layer 402. In some embodiments, the first barrier layer 106 is in direct contact with an upper surface of the first ferroelectric layer 108 and a lower surface of the second ferroelectric layer 502, and the second barrier layer 402 is in direct contact with an upper surface of the second ferroelectric layer 502.

A bandgap energy of the first barrier layer 106 is greater than both a bandgap energy of the first ferroelectric layer 108 and a bandgap energy of the second ferroelectric layer 502. Thus, the first barrier layer 106 forms a first electron/hole barrier between the first ferroelectric layer 108 and the second ferroelectric layer 502.

Further, a bandgap energy of the second barrier layer 402 is greater than a bandgap energy of the second ferroelectric layer 502. Thus, the second barrier layer 402 forms a second electron/hole barrier between the second ferroelectric layer 502 and the second electrode layer 110. In some embodiments, the bandgap energy of the second barrier layer 402 may also be greater than that of the first ferroelectric layer 108. In some other embodiments, the bandgap energy of the second barrier layer 402 may alternatively be less than that of the first ferroelectric layer 108.

FIG. 8 illustrates a cross-sectional view 800 of some embodiments of the ferroelectric capacitor 101 of FIG. 6, further comprising a third barrier layer 802 between the second ferroelectric layer 502 and the second electrode layer 110.

The third barrier layer 802 is on the second ferroelectric layer 502. The second electrode layer 110 is on the third barrier layer 802. In some embodiments, each of the first electrode layer 104, the first barrier layer 106, the first ferroelectric layer 108, the second barrier layer 402, the second ferroelectric layer 502, the third barrier layer 802, and the second electrode layer 110 are arranged along a common vertical axis 804. The common vertical axis 804 is vertical relative to a horizontal upper surface of the substrate 102. In some embodiments, the first barrier layer 106 is in direct contact with a lower surface of the first ferroelectric layer 108, the second barrier layer 402 is in direct contact with an upper surface of the first ferroelectric layer 108, the second barrier layer 402 is in direct contact with a lower surface of the second ferroelectric layer 502, and the third barrier layer 802 is in direct contact with an upper surface of the second ferroelectric layer 502.

A bandgap energy of the first barrier layer 106 is greater than a bandgap energy of the first ferroelectric layer 108. Thus, the first barrier layer 106 forms a first electron/hole barrier between the first ferroelectric layer 108 and the first electrode layer 104. Further, a bandgap energy of the second barrier layer 402 is greater than both a bandgap energy of the first ferroelectric layer 108 and a bandgap energy of the second ferroelectric layer 502. Thus, the second barrier layer 402 forms a second electron/hole barrier between the first ferroelectric layer 108 and the second ferroelectric layer 502. Furthermore, a bandgap energy of the third barrier layer 802 is greater than the bandgap energy of the second ferroelectric layer 502. Thus, the third barrier layer 802 forms a third electron/hole barrier between the second ferroelectric layer 502 and the second electrode layer 110. By including the third barrier layer 802 and thus the third electron/hole barrier in the ferroelectric capacitor 101, a leakage of the ferroelectric capacitor 101 may be further reduced.

In some embodiments, the bandgap energies of each of the barrier layers (e.g., 106, 402, 802) are greater than the bandgap energies of each of the ferroelectric layers (e.g., 108, 502). In some other embodiments, a bandgap energy of a barrier layer is greater than that of a neighboring ferroelectric layer, but may be less than that of a non-neighboring ferroelectric layer. For example, in some such embodiments, the bandgap energy of the first barrier layer 106 is greater than the bandgap energy of the first ferroelectric layer 108; the bandgap energy of the second barrier layer 402 is greater than the both the bandgap energy of the first ferroelectric layer 108 and the bandgap energy of the second ferroelectric layer 502; the bandgap energy of the third barrier layer 802 is greater than the bandgap energy of the second ferroelectric layer 502; the bandgap energy of the first barrier layer 106 may be greater than or less than the bandgap energy of the second ferroelectric layer 502; and the bandgap energy of the third barrier layer 802 may be greater than or less than the bandgap energy of the first ferroelectric layer 108.

The substrate 102 may, for example, comprise silicon, germanium, or some other suitable material. The first electrode layer 104 and/or the second electrode layer 110 may, for example, comprise titanium, titanium nitride, tantalum, tantalum nitride, tungsten, platinum, iridium, ruthenium, molybdenum, ruthenium oxide, or some other suitable material. The first barrier layer 106, the second barrier layer 402, and/or the third barrier layer 802 may, for example, comprise aluminum oxide, silicon dioxide, magnesium oxide, lithium oxide, or some other suitable material and may be amorphous. The first ferroelectric layer 108 and/or the second ferroelectric layer 502 may, for example, comprise a binary oxide (e.g., hafnium oxide or the like), a ternary oxide (e.g., hafnium silicate, hafnium zirconate, barium titanate, lead titanate, strontium titanate, calcium manganite, bismuth ferrite, aluminum scandium nitride, aluminum gallium nitride, aluminum yttrium nitride, silicon doped hafnium oxide, zirconium doped hafnium oxide, yttrium doped hafnium oxide, aluminum doped hafnium oxide, gadolinium doped hafnium oxide, strontium doped hafnium oxide, lanthanum doped hafnium oxide, scandium doped hafnium oxide, germanium doped hafnium oxide, or the like), a quaternary oxide (e.g., lead zirconate, titanate, barium strontium titanate, strontium bismuth tantalate, or the like), or some other suitable material.

In some embodiments, the barrier layers (e.g., 106, 402, 802) comprise a same barrier material. In some other embodiments, the barrier layers comprise different barrier materials. In some embodiments, the ferroelectric layers comprise a same ferroelectric material. In some other embodiments, the ferroelectric layers comprise different ferroelectric materials. In some embodiments, the electrode layers comprise a same conductive material. In some other embodiments, the electrode layers comprise different conductive materials.

In some embodiments, the first electrode layer 104 has a thickness of about 1 angstrom to 500 angstroms or some other suitable thickness. In some embodiments, the first barrier layer 106 has a thickness of about 1 angstrom to 50 angstroms or some other suitable thickness. In some embodiments, the first ferroelectric layer 108 has a thickness of about 1 angstrom to 500 angstroms or some other suitable thickness. In some embodiments, the second barrier layer 402 has a thickness of about 1 angstrom to 50 angstroms or some other suitable thickness. In some embodiments, the second ferroelectric layer 502 has a thickness of about 1 angstrom to 500 angstroms or some other suitable thickness. In some embodiments, the third barrier layer 802 has a thickness of about 1 angstrom to 50 angstroms or some other suitable thickness. In some embodiments, the second electrode layer 110 has a thickness of about 1 angstrom to 500 angstroms or some other suitable thickness. In some embodiments, a sum of the thicknesses of the first barrier layer 106, the first ferroelectric layer 108, the second barrier layer 402, the second ferroelectric layer 502, and the third barrier layer 802 is about 10 angstroms to 1000 angstroms or some other suitable value.

In some embodiments, the barrier layers may have similar thicknesses. In some other embodiments, the barrier layers may have different thicknesses. In some embodiments, the ferroelectric layers may have similar thicknesses. In some other embodiments, the ferroelectric layers may have different thicknesses. In some embodiments, the electrode layers may have similar thicknesses. In some other embodiments, the electrode layers may have different thicknesses.

In some embodiments, a width of the first electrode layer 104 is about 500 angstroms to 5000 angstroms or some other suitable value. In some embodiments, a width of the second electrode layer 110 is about 500 angstroms to 5000 angstroms or some other suitable value. In some embodiments, a width of the first electrode layer 104 may be different from a width of the second electrode layer 110.

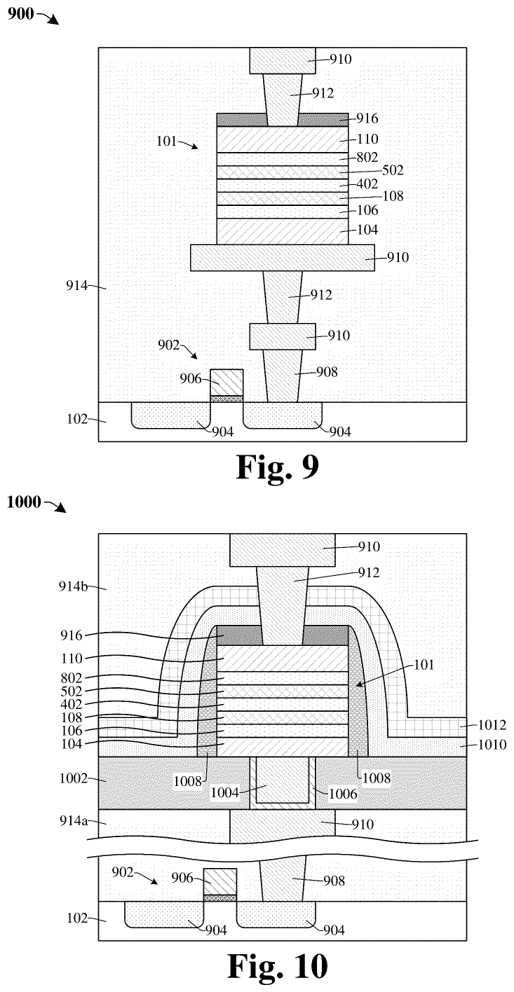

FIG. 9 illustrates a cross-sectional view 900 of some embodiments of an integrated chip including the ferroelectric capacitor 101 of FIG. 8 over a transistor device 902.

The transistor device 902 is arranged along the substrate 102. In some embodiments, the transistor device 902 includes a pair of source/drains 904 and a gate 906. The integrated chip includes a dielectric structure 914 (e.g., one or more dielectric layers) over the substrate 102. A contact 908 is disposed within the dielectric structure 914. In some embodiments, the contact 908 may be arranged on, and electrically coupled to, a source/drain 904 of the transistor device 902. In some other embodiments (not shown), the contact 908 may be arranged on, and electrically coupled to, the gate 906 of the transistor device 902.

The integrated chip further includes metal lines 910 and metal vias 912 over the substrate 102 and coupled to the contact 908. In some embodiments, the ferroelectric capacitor 101 is disposed within the dielectric structure 914 and on a metal line 910. For example, the first electrode layer 104 is on an upper surface of a metal line 910. In some embodiments, a hard mask layer 916 is over the ferroelectric capacitor 101. For example, the hard mask layer 916 is on an upper surface of the second electrode layer 110. In some embodiments, a metal via 912 is over the ferroelectric capacitor 101 and extends from a metal line 910 through the hard mask layer 916 to the upper surface of the second electrode layer 110. In some embodiments, the ferroelectric capacitor 101 is coupled to the transistor so that together they form a one-transistor-one-capacitor (1T1C) type memory cell of a memory device included in the integrated chip.

The hard mask layer 916 may, for example, comprise silicon nitride, silicon oxynitride, or some other suitable material. The contact 908, the metal lines 910, and the metal via 912 may, for example, comprise copper, tungsten, cobalt, titanium, tantalum, or some other suitable material. The dielectric structure 914 may, for example, comprise silicon dioxide, some silicon-oxygen- carbon-hydrogen dielectric, some other low-k dielectric, or some other suitable material.

FIG. 10 illustrates a cross-sectional view 1000 of some other embodiments of an integrated chip including the ferroelectric capacitor 101 of FIG. 8 over a transistor device.

The integrated chip includes a first dielectric structure 914a and a second dielectric structure 914b. A metal line 910 is within the first dielectric structure 914a. A silicon carbide layer 1002 is over a metal line 910 and the first dielectric structure 914a. An extended electrode 1004 is disposed within the silicon carbide layer 1002. In some embodiments, the extended electrode 1004 extends through the silicon carbide layer 1002 to an upper surface of the metal line 910. In some other embodiments, a diffusion barrier layer 1006 is disposed between the extended electrode 1004 and the upper surface of the metal line 910. For example, the diffusion barrier layer lines sidewalls of the silicon carbide layer 1002 and the upper surface of the metal line 910, and the extended electrode 1004 is disposed over the diffusion barrier layer 1006. In some embodiments, the diffusion barrier layer 1006 comprises a conductive material different from that of the extended electrode 1004.

The ferroelectric capacitor 101 is over the extended electrode 1004 and the silicon carbide layer 1002. For example, the first electrode layer 104 is on an upper surface of the extended electrode 1004 and on an upper surface of the silicon carbide layer 1002. In some embodiments, the extended electrode 1004 comprises a conductive material different from that of the first electrode layer 104.

A pair of spacers 1008 are disposed over the silicon carbide layer 1002 and on opposite sides of the ferroelectric capacitor 101. For example, the spacers 1008 are on upper surfaces of the silicon carbide layer 1002 and continuously extend along sidewalls of the first electrode layer 104, the first barrier layer 106, the first ferroelectric layer 108, the second barrier layer 402, the second ferroelectric layer 502, the third barrier layer 802, the second electrode layer 110, and the hard mask layer 916.

An etch stop layer (ESL) 1010 is disposed over the silicon carbide layer 1002, along sides of the spacers 1008, and over the ferroelectric capacitor 101. For example, the ESL 1010 extends along upper surfaces of the silicon carbide layer 1002, along sidewalls of the spacers 1008, and along an upper surface of the hard mask layer 916.

A buffer layer 1012 is disposed over the ESL 1010. For example, the buffer layer 1012 lines sidewalls and upper surfaces of the ESL 1010. The second dielectric structure 914b is over the buffer layer 1012.

A metal via 912 and a metal line 910 are within the second dielectric structure 914b and over the ferroelectric capacitor 101. The metal via 912 extends from the metal line 910 through the second dielectric structure 914b, the buffer layer 1012, the ESL 1010, and the hard mask layer 916 to an upper surface of the second electrode layer 110. In some embodiments, the metal via 912 is directly over the extended electrode 1004.

In some embodiments, the silicon carbide layer 1002 comprises silicon carbide or some other suitable material. In some embodiments, the extended electrode 1004 comprises titanium nitride, platinum, aluminum, copper, gold, titanium, tantalum, tantalum nitride, tungsten, tungsten nitride, an alloy of the aforementioned materials, a combination of the foregoing, or some other suitable material. In some embodiments, the diffusion barrier layer 1006 comprises tantalum nitride or some other suitable material. In some embodiments, the spacers 1008 comprise silicon dioxide, silicon nitride, silicon oxynitride, or some other suitable material. In some embodiments, the ESL 1010 comprises silicon dioxide, silicon nitride, aluminum oxide, aluminum nitride, or some other suitable materiel. In some embodiments, the buffer layer 1012 comprises tetraethyl orthosilicate or some other suitable material.

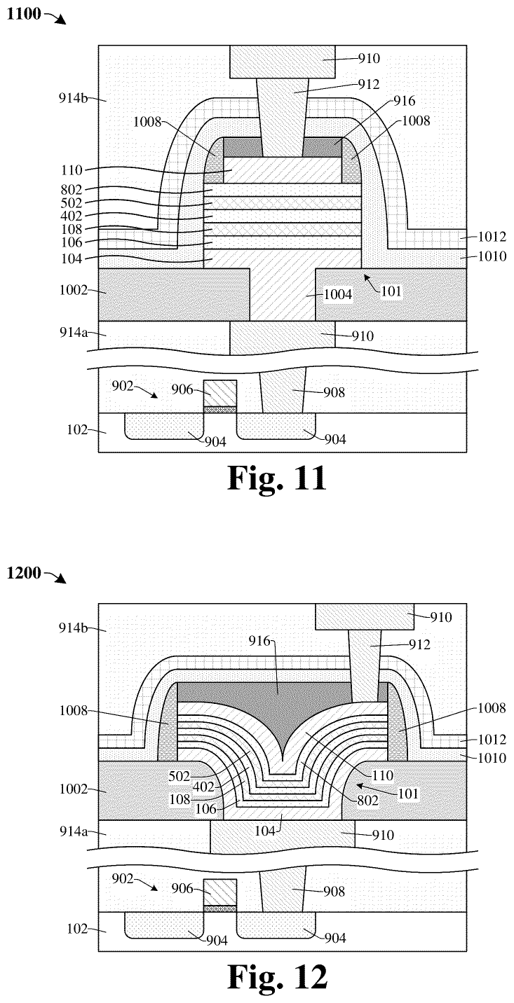

FIG. 11 illustrates a cross-sectional view 1100 of some other embodiments of an integrated chip including the ferroelectric capacitor 101 of FIG. 8 over a transistor device.

In some embodiments, the first electrode layer 104 forms the extended electrode 1004. For example, the first electrode layer 104 extends from over the silicon carbide layer 1002 to between sidewalls of the silicon carbide layer 1002.

In some embodiments, the spacers 1008 are disposed over the third barrier layer 802 and on opposite sides of the second electrode layer 110 and the hard mask layer 916. For example, the spacers 1008 are on upper surfaces of the third barrier layer 802 (or whichever layer is immediately below the second electrode layer 110) and continuously extend along sidewalls of the second electrode layer 110 and the hard mask layer 916.

In some embodiments, the ESL 1010 continuously extends along upper surfaces of the silicon carbide layer 1002, along sidewalls of the first electrode layer 104, the first barrier layer 106, the first ferroelectric layer 108, the second barrier layer 402, the second ferroelectric layer 502, the third barrier layer 802, and the spacers 1008, and along an upper surface of the hard mask layer 916.

FIG. 12 illustrates a cross-sectional view 1200 of some other embodiments of an integrated chip including the ferroelectric capacitor 101 of FIG. 8 over a transistor device.

In some embodiments, the first electrode layer 104 lines upper surfaces of the silicon carbide layer 1002, sidewalls of the silicon carbide layer 1002, and an upper surface of a metal line 910. The first barrier layer 106 lines upper surfaces and sidewalls of the first electrode layer 104. The first ferroelectric layer 108 lines upper surfaces and sidewalls of the first barrier layer 106. The second barrier layer 402 lines upper surfaces and sidewalls of the first ferroelectric layer 108. The second ferroelectric layer 502 lines upper surfaces and sidewalls of the second barrier layer 402. The third barrier layer 802 lines upper surfaces and sidewalls of the second ferroelectric layer 502. The hard mask layer 916 lines upper surfaces and sidewalls of the third barrier layer 802.

In some embodiments, the hard mask layer 916 extends below an uppermost surface of the second electrode layer 110. In some embodiments, the hard mask layer 916 extends below an uppermost surface of the first electrode layer 104. In some embodiments, the metal via 912 that is over and in contact with the second electrode layer 110 is laterally offset from a horizontal center of the ferroelectric capacitor 101. As a result, the metal via 912 may be directly over the silicon carbide layer 1002.

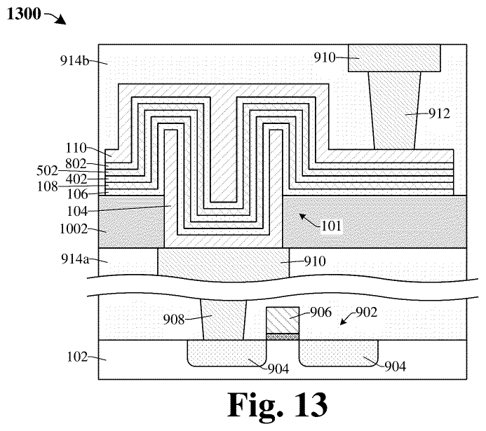

FIG. 13 illustrates a cross-sectional view 1300 of some other embodiments of an integrated chip including the ferroelectric capacitor 101 of FIG. 8 over a transistor device.

In some embodiments, the first electrode layer 104 extends over the silicon carbide layer 1002, along sidewalls of the silicon carbide layer 1002, and along an upper surface of a metal line 910 in a U-shape. In some embodiments, the first barrier layer 106 lines an upper surface of the silicon carbide layer 1002, sidewalls of the first electrode layer 104, and upper surfaces of the first electrode layer 104.

Although FIGS. 9-14 illustrate integrated chips including the ferroelectric capacitor 101 of FIG. 8, it will be appreciated that in some other embodiments, any of the integrated chips of FIGS. 9-14 could alternatively include the ferroelectric capacitors of any of FIGS. 1, 3, 4, 5, 6, and 7.

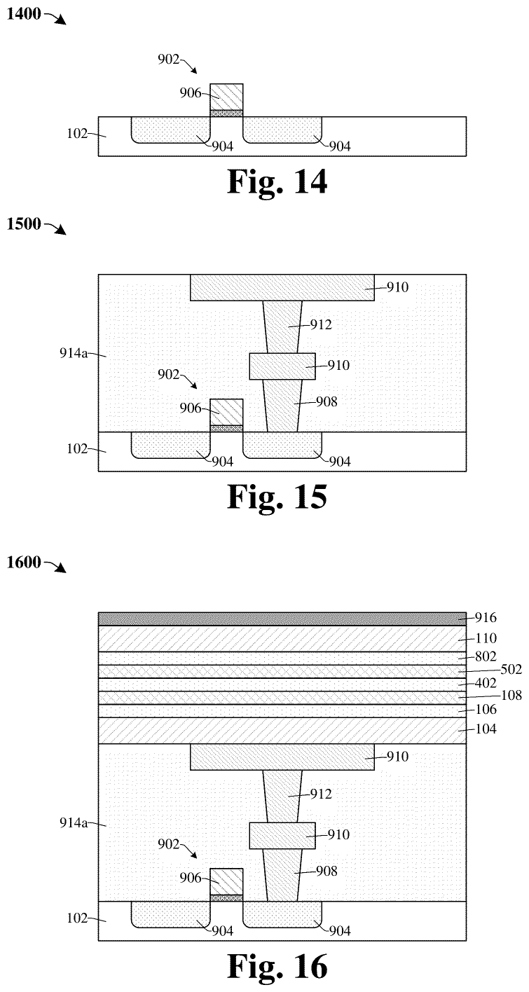

FIGS. 14-20 illustrate cross-sectional views 1400-2000 of some embodiments of a method for forming an integrated chip including a ferroelectric capacitor 101 over a transistor device 902, the ferroelectric capacitor 101 including a first barrier layer 106. Although FIGS. 14-20 are described in relation to a method, it will be appreciated that the structures disclosed in FIGS. 14-20 are not limited to such a method, but instead may stand alone as structures independent of the method.

As shown in cross-sectional view 1400 of FIG. 14, a transistor device 902 is formed along a substrate 102. For example, the transistor device 902 may be formed by depositing a gate material over the substrate, patterning the gate material to form the gate 906, and doping the substrate 102 with the gate 906 in place to form source/drains 904 along the substrate 102.

As shown in cross-sectional view 1500 of FIG. 15, a first dielectric structure 914a (e.g., comprising one or more dielectric layers) is formed over the transistor device 902 and interconnect is formed within the first dielectric structure 914a. For example, a first dielectric structure 914a is formed over the substrate 102, a contact 908, metal lines 910, and a metal via 912 are formed within a first dielectric structure 914a. The interconnect may be formed by patterning the first dielectric structure 914a to form openings in the first dielectric structure 914a, depositing one or more conductive materials in the openings, and planarizing the conductive materials. In some embodiments, the interconnect may be formed over a source/drain 904 of the transistor device 902. In some other embodiments, the interconnect may be formed over the gate 906 of the transistor device 902.

The first dielectric structure 914a may be formed by depositing one or more dielectric layers over the substrate 102. The one or more dielectric layers may, for example, comprise silicon dioxide, some silicon-oxygen-carbon-hydrogen dielectric, some other low-k dielectric, or some other suitable material, and may be deposited by a chemical vapor deposition (CVD) process, a physical vapor deposition (PVD) process, an atomic layer deposition (ALD) process, or some other suitable process.

In some embodiments, the patterning performed for forming the interconnect may comprise forming a masking layer (e.g., a photoresist masking layer) over the first dielectric structure 914a and etching (e.g., dry etching) the first dielectric structure 914a according to the masking layer (e.g., etching the first dielectric structure 914a with the masking layer in place). In some embodiments, the conductive materials deposited to form the interconnect (e.g., the contact 908, the metal via 912, and the metal lines 910) may comprise copper, tungsten, cobalt, titanium, tantalum, or some other suitable material and may be deposited by a sputtering process, a CVD process, a PVD process, an ALD process, or some other suitable process. In some embodiments, the planarization process may, for example, be or comprise a chemical mechanical planarization (CMP) or some other suitable process.

As shown in cross-sectional view 1600 of FIG. 16, a first electrode layer 104 is deposited over the first dielectric structure 914a and over a metal line 910. A first barrier layer 106 is deposited over the first electrode layer 104. A first ferroelectric layer 108 is deposited over the first barrier layer 106. A second barrier layer 402 is deposited over the first ferroelectric layer 108. A second ferroelectric layer 502 is deposited over the second barrier layer 402. A third barrier layer 802 is deposited over the second ferroelectric layer 502. A second electrode layer 110 is deposited over the third barrier layer 802. A hard mask layer 916 is deposited over the second electrode layer 110.

In some embodiments, the first electrode layer 104 may comprise titanium, titanium nitride, tantalum, tantalum nitride, tungsten, platinum, iridium, ruthenium, molybdenum, ruthenium oxide, or some other suitable material and may be deposited over the metal line 910 by a sputtering process, a CVD process, a PVD process, an ALD process, or some other suitable process. In some embodiments, the first barrier layer 106 may be amorphous, may comprise aluminum oxide, silicon dioxide, magnesium oxide, lithium oxide, or some other suitable material, and may be deposited over the first electrode layer 104 by a CVD process, a PVD process, an ALD process, or some other suitable process. In some embodiments, the first ferroelectric layer 108 may comprise a binary oxide, a ternary oxide, a quaternary oxide, or some other suitable material and may be deposited over the first barrier layer 106 by a CVD process, a PVD process, an ALD process, or some other suitable process. In some embodiments, the second barrier layer 402 may be amorphous, may comprise aluminum oxide, silicon dioxide, magnesium oxide, lithium oxide, or some other suitable material, and may be deposited over the first ferroelectric layer 108 by a CVD process, a PVD process, an ALD process, or some other suitable process. In some embodiments, the second ferroelectric layer 502 may comprise a binary oxide, a ternary oxide, a quaternary oxide, or some other suitable material and may be deposited over the second barrier layer 402 by a CVD process, a PVD process, an ALD process, or some other suitable process. In some embodiments, the third barrier layer 802 may be amorphous, may comprise aluminum oxide, silicon dioxide, magnesium oxide, lithium oxide, or some other suitable material, and may be deposited over the second ferroelectric layer 502 by a CVD process, a PVD process, an ALD process, or some other suitable process. In some embodiments, the second electrode layer 110 may comprise titanium, titanium nitride, tantalum, tantalum nitride, tungsten, platinum, iridium, ruthenium, molybdenum, ruthenium oxide, or some other suitable material and may be deposited over the third barrier layer 802 by a sputtering process, a CVD process, a PVD process, an ALD process, or some other suitable process. In some embodiments, the hard mask layer 916 may comprise silicon nitride, silicon oxynitride, or some other suitable material, and may be deposited over the second electrode layer 110 by a CVD process, a PVD process, an ALD process, or some other suitable process.

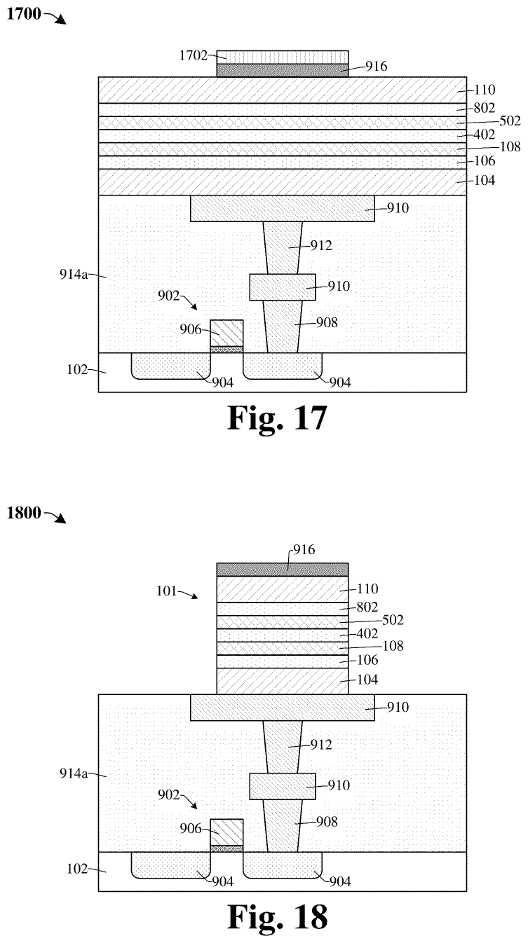

As shown in cross-sectional view 1700 of FIG. 17, the hard mask layer 916 is patterned. In some embodiments, the patterning comprises forming a photoresist layer 1702 over the hard mask layer 916 and etching the hard mask layer 916 according to the photoresist layer 1702. The etching may comprise a dry etching process such as, for example, a plasma etching process, a reactive ion etching process, an ion beam etching process, or some other suitable process. The photoresist layer 1702 may be removed after the etching.

As shown in cross-sectional view 1800 of FIG. 18, the second electrode layer 110, the third barrier layer 802, the second ferroelectric layer 502, the second barrier layer 402, the first ferroelectric layer 108, the first barrier layer 106, and the first electrode layer 104 are etched according to the patterned hard mask layer 916 to form (e.g., delimit) the ferroelectric capacitor 101. The etching may, for example, comprise a dry etching process or some other suitable process.

As shown in cross-sectional view 1900 of FIG. 19, a second dielectric structure 914b is formed over and on opposite sides of the ferroelectric capacitor 101. The second dielectric structure 914b may be formed by depositing one or more dielectric layers over the substrate 102. The one or more dielectric layers may, for example, comprise silicon dioxide, some silicon- oxygen-carbon-hydrogen dielectric, some other low-k dielectric, or some other suitable material, and may be deposited by a CVD process, a PVD process, an ALD process, or some other suitable process.

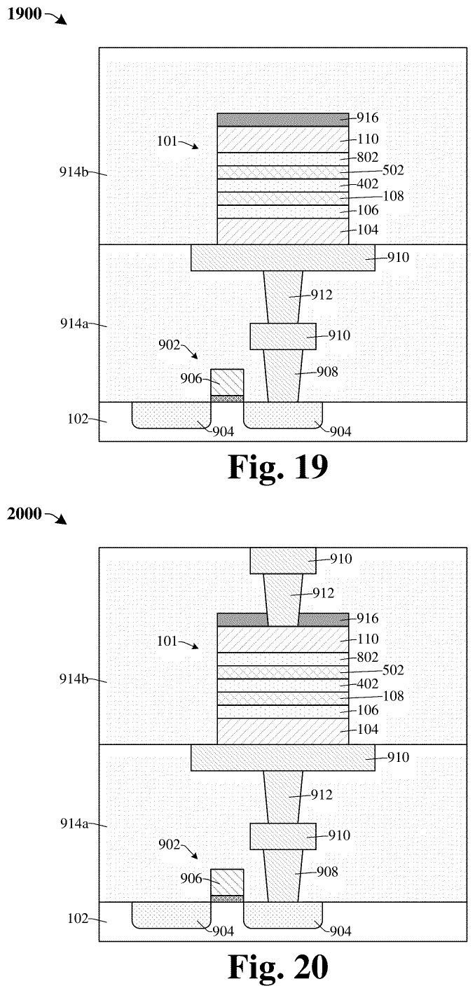

As shown in cross-sectional view 2000 of FIG. 20, interconnect is formed within the second dielectric structure 914b. For example, a metal via 912 is formed within hard mask layer 916 and the second dielectric structure 914b, and a metal line 910 is formed over the metal via 912 within the second dielectric structure 914b. In some embodiments, the metal line 910 and the metal via 912 are formed by patterning the second dielectric structure 914b and the hard mask layer 916, depositing a conductive material over the patterned second dielectric structure 914b, and planarizing the conductive material. The conductive material may, for example, comprise copper, tungsten, cobalt, titanium, tantalum, or some other suitable material and may be deposited by a sputtering process, a CVD process, a PVD process, an ALD process, or some other suitable process.

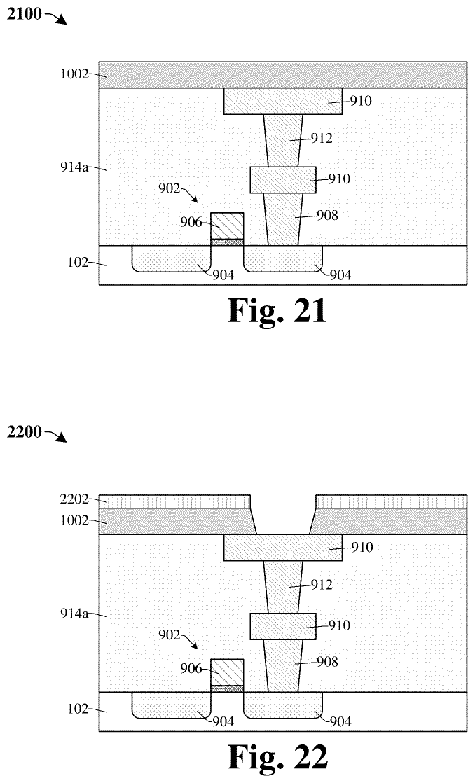

FIGS. 21-28 illustrate cross-sectional views 2100-2800 of some other embodiments of a method for forming an integrated chip including a ferroelectric capacitor 101 over a transistor device 902, the ferroelectric capacitor 101 including a first barrier layer 106. Although FIGS. 21-28 are described in relation to a method, it will be appreciated that the structures disclosed in FIGS. 21-28 are not limited to such a method, but instead may stand alone as structures independent of the method.

As shown in cross-sectional view 2100 of FIG. 21, a transistor device 902 is formed along a substrate 102 (e.g., as illustrated in FIG. 14); a first dielectric structure 914a is formed over the transistor device 902 and interconnect (e.g., 908, 910, 912) is formed within the first dielectric structure 914a (e.g., as illustrated in FIG. 15); and a silicon carbide layer 1002 is deposited over the first dielectric structure 914a and over a metal line 910. In some embodiments, the silicon carbide layer 1002 is deposited over the substrate 102 by a CVD process, a PVD process, an ALD process, or some other suitable process.

As shown in cross-sectional view 2200 of FIG. 22, the silicon carbide layer 1002 is patterned to form an opening in the silicon carbide layer 1002 over the metal line 910. In some embodiments, the patterning comprises forming a photoresist layer 2202 over the silicon carbide layer 1002 and etching the silicon carbide layer 1002 according to the photoresist layer 2202. The etching may, for example, comprise a dry etching process or some other suitable process. The photoresist layer 2202 may be removed after the etching.

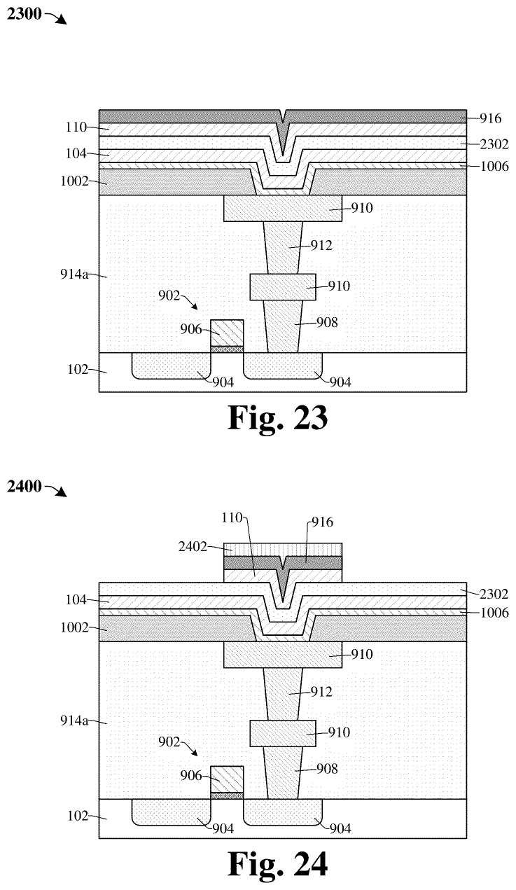

As shown in cross-sectional view 2300 of FIG. 23, a diffusion barrier layer 1006 is deposited over the silicon carbide layer 1002 and over the metal line 910 between sidewalls of the silicon carbide layer 1002. A first electrode layer 104 is deposited over diffusion barrier layer 1006. A ferroelectric structure 2302 (e.g., comprising a first barrier layer 106, a first ferroelectric layer 108, a second barrier layer 402, a second ferroelectric layer 502, and a third barrier layer 802) is formed over the first electrode layer 104. A second electrode layer 110 is deposited over the ferroelectric structure 2302. A hard mask layer 916 is deposited over the second electrode layer 110.

As shown in cross-sectional view 2400 of FIG. 24, the hard mask layer 916 and the second electrode layer 110 are patterned. In some embodiments, the patterning comprises forming a photoresist layer 2402 over the hard mask layer 916 and etching the hard mask layer 916 and the second electrode layer 110 according to the photoresist layer 2402. The etching may, for example, comprise a dry etching process or some other suitable process. The photoresist layer 2402 may be removed after the etching.

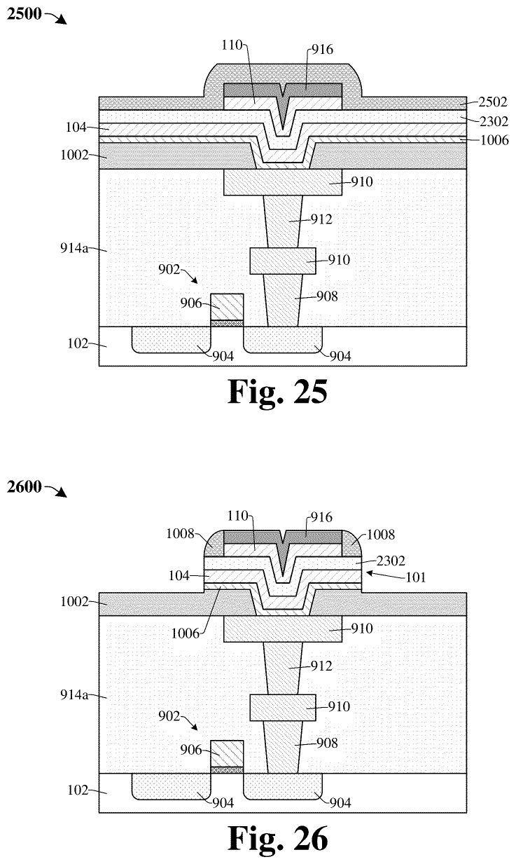

As shown in cross-sectional view 2500 of FIG. 25, a spacer layer 2502 is deposited over the hard mask layer 916 and over the ferroelectric structure 2302. In some embodiments, the spacer layer 2502 comprises silicon dioxide, silicon nitride, silicon oxynitride, or some other suitable material and may be deposited by a CVD process, a PVD process, an ALD process, or some other suitable process.

As shown in cross-sectional view 2600 of FIG. 26, the spacer layer (e.g., 2502 of FIG. 25) is etched to form (e.g., delimit) a pair of spacers 1008 from the spacer layer. The etching removes the spacer layer from over a portion of the silicon carbide layer 1002 and from over the hard mask layer 916. The ferroelectric structure 2302, the first electrode layer 104, and the diffusion barrier layer 1006 are also etched to form (e.g., delimit) the ferroelectric capacitor 101. In some embodiments, the etching may extend into the silicon carbide layer 1002 and thus a portion of the silicon carbide layer 1002 may be removed. The etching may, for example, comprise a dry etching process or some other suitable process.

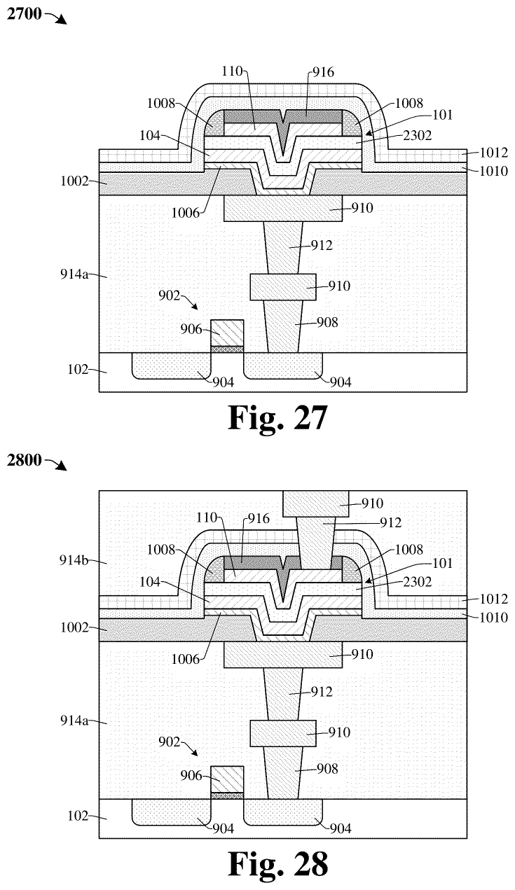

As shown in cross-sectional view 2700 of FIG. 27, an ESL 1010 is deposited over the silicon carbide layer 1002, over the spacers 1008, and over the hard mask layer 916. Further, a buffer layer 1012 layer is deposited over the ESL 1010. In some embodiments, the ESL 1010 comprises silicon dioxide, silicon nitride, aluminum oxide, aluminum nitride, or some other suitable material and may be deposited by a CVD process, a PVD process, an ALD process, or some other suitable process. In some embodiments, the buffer layer 1012 comprises tetraethyl orthosilicate or some other suitable material and may be deposited by a CVD process, a PVD process, an ALD process, or some other suitable process.

As shown in cross-sectional view 2800 of FIG. 28, a second dielectric structure 914b is formed over and on opposite sides of the ferroelectric capacitor 101 (e.g., as illustrated in FIG. 19), and interconnect (e.g., 912, 910) is formed within the second dielectric structure 914b (e.g., as illustrated in FIG. 20). In some embodiments, a via opening (not shown) is etched in the second dielectric structure 914b, the buffer layer 1012, the ESL 1010, and the hard mask layer 916 to uncover an upper surface of the second electrode layer 110, and a metal via 912 is subsequently formed in the via opening on the second electrode layer 110.

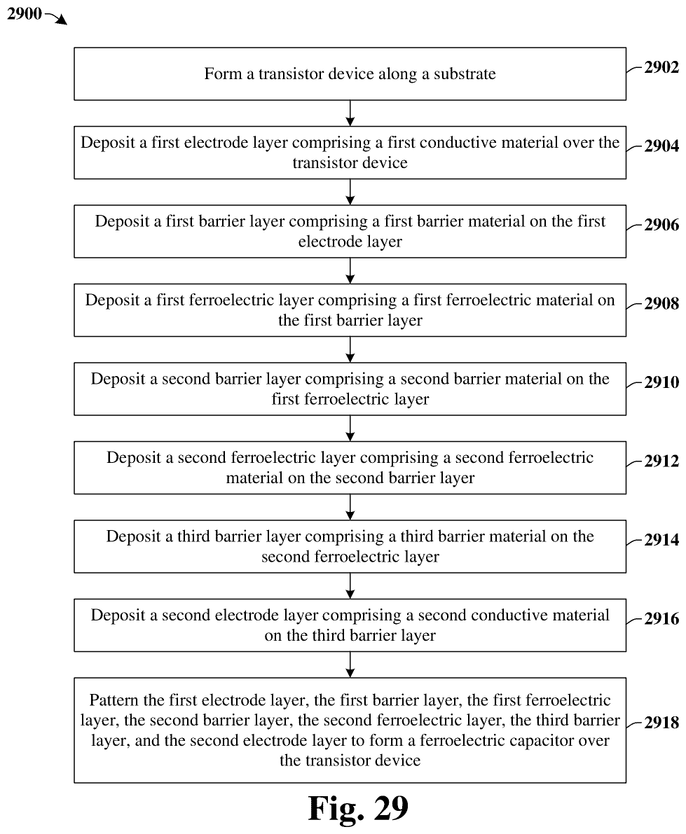

FIG. 29 illustrates a flow diagram of some embodiments of a method 2900 for forming an integrated chip including a ferroelectric capacitor over a transistor device, the ferroelectric capacitor including a first barrier layer. While method 2900 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 2902, form a transistor device along a substrate. FIG. 14 illustrates a cross-sectional view 1400 of some embodiments corresponding to block 2902.

At block 2904, deposit a first electrode layer comprising a first conductive material over the transistor device. FIG. 16 illustrates a cross-sectional view 1600 of some embodiments corresponding to block 2904.

At block 2906, deposit a first barrier layer comprising a first barrier material on the first electrode layer. FIG. 16 illustrates a cross-sectional view 1600 of some embodiments corresponding to block 2906.

At block 2908, deposit a first ferroelectric layer comprising a first ferroelectric material on the first barrier layer. FIG. 16 illustrates a cross-sectional view 1600 of some embodiments corresponding to block 2908.

At block 2910, deposit a second barrier layer comprising a second barrier material on the first ferroelectric layer. FIG. 16 illustrates a cross-sectional view 1600 of some embodiments corresponding to block 2910.

At block 2912, deposit a second ferroelectric layer comprising a second ferroelectric material on the second barrier layer. FIG. 16 illustrates a cross-sectional view 1600 of some embodiments corresponding to block 2912.

At block 2914, deposit a third barrier layer comprising a third barrier material on the second ferroelectric layer. FIG. 16 illustrates a cross-sectional view 1600 of some embodiments corresponding to block 2914.

At block 2916, deposit a second electrode layer comprising a second conductive material on the third barrier layer. FIG. 16 illustrates a cross-sectional view 1600 of some embodiments corresponding to block 2916.

At block 2918, pattern the first electrode layer, the first barrier layer, the first ferroelectric layer, the second barrier layer, the second ferroelectric layer, the third barrier layer, and the second electrode layer to form a ferroelectric capacitor over the transistor device. FIGS. 17 and 18 illustrate cross-sectional views 1700, 1800 of some embodiments corresponding to block 2918.

The first barrier material, the second barrier material, and the third barrier material are different from the first conductive material, the second conductive material, the first ferroelectric material, and the second ferroelectric material. A bandgap energy of the first barrier material is greater than a bandgap energy of the first ferroelectric material. In some embodiments, the bandgap energy of the first barrier material is also greater than a bandgap energy of the second ferroelectric material. In some other embodiments, the bandgap energy of the first barrier material is less than the bandgap energy of the second ferroelectric material. A bandgap energy of the second barrier material is greater than the bandgap energy of the first ferroelectric material and the bandgap energy of the second ferroelectric material. A bandgap energy of the third barrier material is greater than a bandgap energy of the second ferroelectric material. In some embodiments, the bandgap energy of the third barrier material is also greater than a bandgap energy of the first ferroelectric material. In some other embodiments, the bandgap energy of the third barrier material is less than the bandgap energy of the first ferroelectric material. In some examples, the first barrier material, the second barrier material, and the third barrier material are or comprise electrically insulative materials, amorphous solids, amorphous insulators, or some other suitable material(s).

Thus, the present disclosure relates to a ferroelectric memory device and a method for forming a ferroelectric memory device including a barrier layer neighboring a ferroelectric layer for improving a performance of the memory device.

Accordingly, in some embodiments, the present disclosure relates to an integrated chip. The integrated chip comprises a first ferroelectric layer over a substrate. A first electrode layer is over the substrate and on a first side of the first ferroelectric layer. A second electrode layer is over the substrate and on a second side of the first ferroelectric layer, opposite the first side. A first barrier layer is between the first ferroelectric layer and the first electrode layer. A bandgap energy of the first barrier layer is greater than a bandgap energy of the first ferroelectric layer.

In other embodiments, the present disclosure relates to an integrated chip. The integrated chip comprises a first electrode layer. The first electrode layer comprises a first conductive material and is arranged over a substrate along a common vertical axis that is vertical relative to a horizontal upper surface of the substrate. A second electrode layer comprises a second conductive material and is arranged over the substrate along the common vertical axis. A first ferroelectric layer comprises a first ferroelectric material and is arranged along the common vertical axis and vertically between the first electrode layer and the second electrode layer. A first barrier layer comprises a first barrier material, different from the first ferroelectric material, the first conductive material, and the second conductive material, and is arranged along the common vertical axis and vertically between the first ferroelectric layer and the first electrode layer. A conduction band edge energy of the first barrier layer is greater than a conduction band edge energy of the first ferroelectric layer. Further, a valence band edge energy of the first barrier layer is less than a valence band edge energy of the first ferroelectric layer.

In yet other embodiments, the present disclosure relates to a method for forming an integrated chip. The method comprises forming a transistor device along a substrate. A first electrode layer comprising a first conductive material is deposited over the transistor device. A first barrier layer comprising a first barrier material, different from the first conductive material, is deposited on the first electrode layer. A first ferroelectric layer comprising a first ferroelectric material, different from the first barrier material, is deposited on the first barrier layer. A bandgap energy of the first ferroelectric layer is less than a bandgap energy of the first barrier layer. A second barrier layer comprising a second barrier material, different from the first ferroelectric material, is deposited on the first ferroelectric layer. A bandgap energy of the second barrier layer is greater than the bandgap energy of the first ferroelectric layer. A second ferroelectric layer comprising a second ferroelectric material, different from the first barrier material and the second barrier material, is deposited on the second barrier layer. A bandgap energy of the second ferroelectric layer is less than the bandgap energy of the second barrier layer. A third barrier layer comprising a third barrier material, different from the first ferroelectric material and the second ferroelectric material, is deposited on the second ferroelectric layer. A bandgap energy of the third barrier layer is greater than the bandgap energy of the second ferroelectric layer. A second electrode layer comprising a second conductive material, different from the third barrier material, is deposited on the third barrier layer. The first electrode layer, the first barrier layer, the first ferroelectric layer, the second barrier layer, the second ferroelectric layer, the third barrier layer, and the second electrode layer are patterned.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a first ferroelectric layer over a substrate;
a first electrode layer over the substrate and on a first side of the first ferroelectric layer;
a second electrode layer over the substrate and on a second side of the first ferroelectric layer, opposite the first side; and
a first barrier layer between the first ferroelectric layer and the first electrode layer, wherein a bandgap energy of the first barrier layer is greater than a bandgap energy of the first ferroelectric layer.

2. The integrated chip of claim 1, further comprising:
a second ferroelectric layer arranged vertically between the first barrier layer and the first electrode layer, wherein the bandgap energy of the first barrier layer is greater than a bandgap energy of the second ferroelectric layer.

3. The integrated chip of claim 1, further comprising:
a second barrier layer arranged vertically between the first ferroelectric layer and the second electrode layer, wherein a bandgap energy of the second barrier layer is greater than the bandgap energy of the first ferroelectric layer.

4. The integrated chip of claim 3, further comprising:
a second ferroelectric layer arranged vertically between the second barrier layer and the second electrode layer, wherein the bandgap energy of the second barrier layer is greater than a bandgap energy of the second ferroelectric layer; and
a third barrier layer arranged vertically between the second ferroelectric layer and the second electrode layer, wherein a bandgap energy of the third barrier layer is greater than the bandgap energy of the second ferroelectric layer.

5. The integrated chip of claim 1, wherein the first barrier layer comprises an electrically insulative material.

6. The integrated chip of claim 5, wherein the electrically insulative material is an amorphous solid.

7. The integrated chip of claim 1, wherein a thickness of the first barrier layer is less than a thickness of the first ferroelectric layer, a thickness of the first electrode layer, and a thickness of the second electrode layer.

8. The integrated chip of claim 1, wherein the first barrier layer is in direct contact with an upper surface of the first ferroelectric layer.

9. The integrated chip of claim 1, wherein the first barrier layer is in direct contact with a lower surface of the first ferroelectric layer.

10. The integrated chip of claim 1, wherein a dielectric continuously extends along a sidewall of the first barrier layer and a sidewall of the first ferroelectric layer.

11. An integrated chip, comprising:
a first electrode layer comprising a first conductive material arranged over a substrate along a common vertical axis that is vertical relative to a horizontal upper surface of the substrate;
a second electrode layer comprising a second conductive material arranged over the substrate along the common vertical axis;
a first ferroelectric layer comprising a first ferroelectric material arranged along the common vertical axis and vertically between the first electrode layer and the second electrode layer; and
a first barrier layer comprising a first barrier material, different from the first ferroelectric material, the first conductive material, and the second conductive material, arranged along the common vertical axis and vertically between the first ferroelectric layer and the first electrode layer, wherein a conduction band edge energy of the first barrier layer is greater than a conduction band edge energy of the first ferroelectric layer, and wherein a valence band edge energy of the first barrier layer is less than a valence band edge energy of the first ferroelectric layer.

12. The integrated chip of claim 11, wherein the first barrier layer is on an upper surface of the first electrode layer, the first ferroelectric layer is on an upper surface of the first barrier layer, and the second electrode layer is on an upper surface of the first ferroelectric layer.

13. The integrated chip of claim 11, wherein the first ferroelectric layer is on an upper surface of the second electrode layer, the first barrier layer is on an upper surface of the first ferroelectric layer, and the first electrode layer is on an upper surface of the first barrier layer.

14. The integrated chip of claim 11, further comprising:
a second ferroelectric layer comprising a second ferroelectric material, different from the first barrier material, arranged along the common vertical axis, wherein the second ferroelectric layer is on an upper surface of the first electrode layer, the first barrier layer is on an upper surface of the second ferroelectric layer, the first ferroelectric layer is on an upper surface of the first barrier layer, and the second electrode layer is on an upper surface of the first ferroelectric layer,
wherein the conduction band edge energy of the first barrier layer is greater than a conduction band edge energy of the second ferroelectric layer, and wherein the valence band edge energy of the first barrier layer is less than a valence band edge energy of the second ferroelectric layer.

15. The integrated chip of claim 11, further comprising:
a second barrier layer comprising a second barrier material, different from the first ferroelectric material, arranged along the common vertical axis, wherein the first barrier layer is on the first electrode layer, the first ferroelectric layer is on the first barrier layer, the second barrier layer is on the first ferroelectric layer, and the second electrode layer is on the second barrier layer,
wherein a conduction band edge energy of the second barrier layer is greater than the conduction band edge energy of the first ferroelectric layer, and wherein a valence band edge energy of the second barrier layer is less than the valence band edge energy of the first ferroelectric layer.

16. The integrated chip of claim 11, wherein the first barrier layer is on an upper surface of the first electrode layer and the first ferroelectric layer is on an upper surface of the first barrier layer, and wherein the integrated chip further comprises:
a second barrier layer comprising a second barrier material, different from the first ferroelectric material, arranged along the common vertical axis and on an upper surface of the first ferroelectric layer, wherein a conduction band edge energy of the second barrier layer is greater than the conduction band edge energy of the first ferroelectric layer, and wherein a valence band edge energy of the second barrier layer is less than the valence band edge energy of the first ferroelectric layer;
a second ferroelectric layer comprising a second ferroelectric material, different from the second barrier material, arranged along the common vertical axis and on an upper surface of the second barrier layer, wherein the conduction band edge energy of the second barrier layer is greater than a conduction band edge energy of the second ferroelectric layer, and wherein the valence band edge energy of the second barrier layer is less than a valence band edge energy of the second ferroelectric layer; and
a third barrier layer comprising a third barrier material, different from the first ferroelectric material and the second ferroelectric material, arranged along the common vertical axis and on an upper surface of the second ferroelectric layer, wherein the second electrode layer is on the third barrier layer, and wherein a conduction band edge energy of the third barrier layer is greater than the conduction band edge energy of the second ferroelectric layer, and wherein a valence band edge energy of the third barrier layer is less than the valence band edge energy of the second ferroelectric layer.

17. The integrated chip of claim 11, further comprising:
a hard mask layer on an upper surface of the second electrode layer.

18. A method for forming an integrated chip, the method comprising:
forming a transistor device along a substrate;
depositing a first electrode layer comprising a first conductive material over the transistor device;
depositing a first barrier layer comprising a first barrier material, different from the first conductive material, on the first electrode layer;
depositing a first ferroelectric layer comprising a first ferroelectric material, different from the first barrier material, on the first barrier layer, wherein a bandgap energy of the first ferroelectric layer is less than a bandgap energy of the first barrier layer;
depositing a second barrier layer comprising a second barrier material, different from the first ferroelectric material, on the first ferroelectric layer, wherein a bandgap energy of the second barrier layer is greater than the bandgap energy of the first ferroelectric layer;
depositing a second ferroelectric layer comprising a second ferroelectric material, different from the first barrier material and the second barrier material, on the second barrier layer, wherein a bandgap energy of the second ferroelectric layer is less than the bandgap energy of the second barrier layer;
depositing a third barrier layer comprising a third barrier material, different from the first ferroelectric material and the second ferroelectric material, on the second ferroelectric layer, wherein a bandgap energy of the third barrier layer is greater than the bandgap energy of the second ferroelectric layer;
depositing a second electrode layer comprising a second conductive material, different from the third barrier material, on the third barrier layer; and
patterning the first electrode layer, the first barrier layer, the first ferroelectric layer, the second barrier layer, the second ferroelectric layer, the third barrier layer, and the second electrode layer.

19. The method of claim 18, further comprising:
depositing a hard mask layer on the second electrode layer before the patterning.

20. The method of claim 19, further comprising:
patterning the hard mask layer to form a patterned hard mask layer,
wherein the patterning of the first electrode layer, the first barrier layer, the first ferroelectric layer, the second barrier layer, the second ferroelectric layer, the third barrier layer, and the second electrode layer comprises etching the first electrode layer. the first barrier layer. the first ferroelectric layer. the second barrier layer. the second ferroelectric layer, the third barrier layer, and the second electrode layer according to the patterned hard mask layer.
